(19) United States
(12) Patent Application Publication
(10) Pub. No.: US 2026/0020292 A1
(43) Pub. Date: Jan. 15, 2026

(54) SUPER-JUNCTION SEMICONDUCTOR DEVICE AND MANUFACTURING METHOD THEREOF

(71) Applicant: Magnachip Semiconductor, Ltd., Cheongju-si (KR)

(72) Inventors: Jiyong LIM, Seoul (KR); Chanho PARK, Seoul (KR); Suyoung MOON, Gwacheon-si (KR); Kihwan KIM, Seoul (KR)

(73) Assignee: Magnachip Semiconductor, Ltd., Cheongju-si (KR)

(21) Appl. No.: 19/189,835

(22) Filed: Apr. 25, 2025

(30) Foreign Application Priority Data
Jul. 10, 2024 (KR) 10-2024-0090966

(51) Int. Cl. H10D 62/10; H10D 30/01; H10D 30/63; H10D 64/00; H10D 84/00

(52) U.S. Cl. CPC H10D 62/106; H10D 30/025; H10D 30/63; H10D 62/124; H10D 64/112; H10D 84/101

(57) ABSTRACT

A super-junction semiconductor device includes a substrate; an active cell disposed on the substrate; an edge termination region configured to surround the active cell; a peripheral region configured to surround the active cell and disposed between the active region and the edge termination region; a first conductivity-type pillar and a second conductivity-type pillar alternately disposed in the active cell, the peripheral region, and the edge termination region; a horizontal-shaped second conductivity-type pillar region disposed on the second conductivity-type pillar in the peripheral region and the edge termination region; and a second conductivity-type charge-sharing region disposed on the horizontal-shaped second conductivity-type pillar region.

### CROSS-REFERENCE TO RELATED APPLICATIONS

This application claims the benefit under 35 USC 119 (a) of Korean Patent Application No. 10-2024-0090966 filed on Jul. 10, 2024, in the Korean Intellectual Property Office, the entire disclosure of which is hereby incorporated by reference for all purposes.

### BACKGROUND

### 1. Field

The following description relates to a super-junction semiconductor device and the manufacturing method thereof.

### 2. Description of the Background

Among power semiconductor devices, a super-junction MOSFET device is a semiconductor device that may ensure low on-resistance and high breakdown voltage by vertically alternating N-pillar or N-drift area and P-pillar area within an epitaxial layer formed on a substrate.

A super-junction MOSFET device can be used in various applications, such as DC-DC converters (power supply devices), inverters, and LCC converters. It may be desirable to ensure the robustness and ruggedness of the di/dt value, which represents the slope of the body diode's reverse recovery current, while also maintaining breakdown voltage, on-resistance, and forward voltage characteristics. If the slope of the diode's reverse recovery current is not properly managed, the device could be damaged due to high reverse voltage and reverse current during the reverse recovery operation of the body diode. This could lead to reliability issues for the device.

In the super-junction MOSFET device, a peripheral region may be disposed between an active cell and an edge termination region. The burnt mark phenomenon caused by device destruction occurs most frequently in a peripheral region near an edge of the super-junction MOSFET device. This phenomenon may occur when a hole current generated when a reverse bias is applied is concentrated near the edge of the peripheral region. To prevent this case, the conventional art uses a method of reducing hole carrier by additionally implementing a Schottky diode or a method of additionally performing helium irradiation or electron beam irradiation to reduce hole carrier lifetime. However, when such methods are used, leakage current or on-state resistance might increase, thereby affecting the device characteristics and also raising the process cost.

To prevent these, it may be desirable to improve the robustness and ruggedness of the slope of the body diode reverse recovery current in the peripheral region and edge termination region disposed in the super-junction MOSFET device by optimizing the hole current path during the reverse recovery.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a super-junction semiconductor device includes a substrate; an active cell disposed on the substrate; an edge termination region configured to surround the active cell; a peripheral region configured to surround the active cell and disposed between the active region and the edge termination region; a first conductivity-type pillar and a second conductivity-type pillar alternately disposed in the active cell, the peripheral region, and the edge termination region; a horizontal-shaped second conductivity-type pillar region disposed on the second conductivity-type pillar in the peripheral region and the edge termination region; and a second conductivity-type charge-sharing region disposed on the horizontal-shaped second conductivity-type pillar region.

The first conductivity-type pillar may include a first conductivity-type first pillar disposed in the active cell; a first conductivity-type second pillar disposed in the peripheral region; a first conductivity-type third pillar disposed in the edge termination region. The second conductivity pillar may include a second conductivity-type first pillar disposed in the active cell; a second conductivity-type second pillar disposed in the peripheral region; a second conductivity-type third pillar disposed in the edge termination region. A vertical direction of the second conductivity-type first pillar may be longer than a vertical direction of the second conductivity-type third pillar.

The horizontal-shaped second conductivity-type pillar region may be connected to the second conductivity-type charge-sharing region.

The super-junction device may further include a first conductivity-type fourth pillar disposed between the second conductivity-type third pillar in the peripheral region and the horizontal-shaped second conductivity-type pillar.

The second conductivity-type charge-sharing region may include a peripheral charge-sharing region disposed in the peripheral region; and an edge termination charge-sharing region disposed in the edge termination region. A charge concentration of the edge termination charge-sharing region is lower than a charge concentration of the peripheral charge-sharing region.

The super-junction semiconductor device may further include a second conductivity-type body region disposed on the second conductivity-type first pillar; a first conductivity-type source region disposed in the second conductivity-type body region; and a second conductivity-type body contact region disposed between the first conductivity-type source region and another first conductivity-type source region in the second conductivity-type body region.

The super-junction semiconductor device may further include a field oxide film disposed on the edge termination charge-sharing region in the edge termination region; a field plate insulating film disposed above an end and sides of the field oxide film toward the peripheral region and on the edge termination charge-sharing region adjacent to the peripheral region; and a gate insulating film disposed in the second conductivity-type body region, the first conductivity-type first pillar, and a predetermined area of the first conductivity-type source region.

The super-junction semiconductor device may further include a gate electrode disposed on the gate insulating film; a field plate disposed on the field insulating film; and a gate runner disposed on the field plate.

The super-junction semiconductor device may further include a peripheral contact region disposed on a peripheral charge-sharing region in the peripheral region; a source electrode disposed on the second conductivity-type body contact region and the peripheral contact region; and a drain electrode disposed under the substrate.

The second conductivity-type second pillar disposed in the peripheral region may include a second conductivity-type 2-1 pillar disposed adjacent to the active cell, and a second conductivity-type 2-2 pillar disposed adjacent to the edge termination region.

The second conductivity-type 2-1 pillar may be connected to the second conductivity-type charge-sharing region and the horizontal-shaped second conductivity-type pillar region.

The second conductivity-type 2-2 pillar may be spaced apart from the horizontal-shaped second conductivity-type pillar region.

In another general aspect, a manufacturing method of a super-junction semiconductor device includes forming a semiconductor substrate; forming plural ones of a vertical-shaped first conductivity-type pillar and a vertical-shaped second conductivity-type pillar in each of an active region, a peripheral region, and an edge termination region of the semiconductor substrate; and forming a horizontal-shaped second conductivity-type pillar on the plural ones of the vertical-shaped first conductivity-type pillar and the vertical-shaped second conductivity-type pillar.

The forming of the plural ones of the vertical-shaped first conductivity-type pillar and the vertical-shaped second conductivity-type pillar may include a first operation of forming a first epitaxial layer on the semiconductor substrate; a second operation of injecting a second conductivity-type ion to the first epitaxial layer at a first interval; a third operation of diffusing the second conductivity-type ion while forming a second epitaxial layer on the first epitaxial layer; and an operation of forming up to a fifth epitaxial layer by repeating the first to third operations.

The manufacturing method may further include a fourth operation of injecting a second conductivity-type ion into the active cell on the fifth epitaxial layer at the first interval, the peripheral region, and the edge termination region at a second interval narrower than the first interval.

The fourth operation may include forming on the fifth epitaxial layer a mask including a first opening in the active cell at the first interval, and a second opening in the peripheral region and the edge termination region at the second interval; and injecting a second conductivity-type ion to the fifth epitaxial layer through the mask. A width of the second opening may be narrower than a width of the first opening.

The width of the second opening may be ½ of the width of the first opening, and the second interval may be ½ of the first interval.

The manufacturing method may further include diffusing the second conductivity-type ion injected into the fifth epitaxial layer to form the vertical-shaped second conductivity-type pillar in the active cell and the horizontal-shaped second conductivity-type pillar in the peripheral region and the edge termination region, while forming a sixth epitaxial layer on the fifth epitaxial layer.

A first thickness in an area where the second conductivity-type ion of the horizontal-shaped second conductivity-type pillar is injected may be thicker than a second thickness of an adjacent area connected to the area by diffusing the second conductivity-type ion.

The manufacturing method may further include forming an edge termination charge-sharing region to be connected to the horizontal-shaped second conductivity-type pillar above an epitaxial layer in the edge termination region; forming a field oxide film on the epitaxial layer in the edge termination charge-sharing region and the edge termination region; forming a gate insulating film on the vertical-shaped first conductivity-type pillar in the active cell of the semiconductor substrate, and forming a field plate insulating film at both ends of the field oxide film; forming a gate electrode on the gate insulating film and a field plate on the field plate insulating film; forming a body region on the vertical-shaped second conductivity-type pillar in the active cell, and forming a peripheral charge-sharing region on the epitaxial layer in the peripheral region to be connected to the vertical-shaped second conductivity-type pillar of the peripheral region, the horizontal-shaped second conductivity-type pillar, and the edge termination charge-sharing region; forming a source region at an upper end of the body region; forming a first insulating film on the gate electrode, the field plate, and the field oxide film; forming a body contact region between the source region and another source region in the body region, and forming a peripheral contact region above the peripheral charge-sharing region; forming a second insulating film on the first insulating film; forming a source electrode connected to the body contact region and the peripheral contact region, and forming a gate runner connected to the field plate; and forming a drain electrode under the semiconductor substrate.

Other features and aspects will be apparent from the following detailed description, the drawings, and the claims.

### DESCRIPTION OF DRAWINGS

FIG. 1 is a plan view of a super-junction semiconductor device according to one embodiment of the present disclosure.

FIG. 2 is a cross-sectional view showing the super-junction semiconductor device shown in FIG. 1 along X-X′.

FIGS. 3 to 19 are cross-sectional views showing a series of processes of a manufacturing method of the super-junction semiconductor device according to one embodiment of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Embodiments of the present disclosure relate to a super-junction semiconductor that may ensure an extended charge-sharing area by forming a single horizontal P-type pillar on the uppermost layer of multiple P-type pillars arranged within a peripheral region and an edge termination region and forming a charge-sharing region on the horizontal P-type pillar, and a manufacturing method thereof.

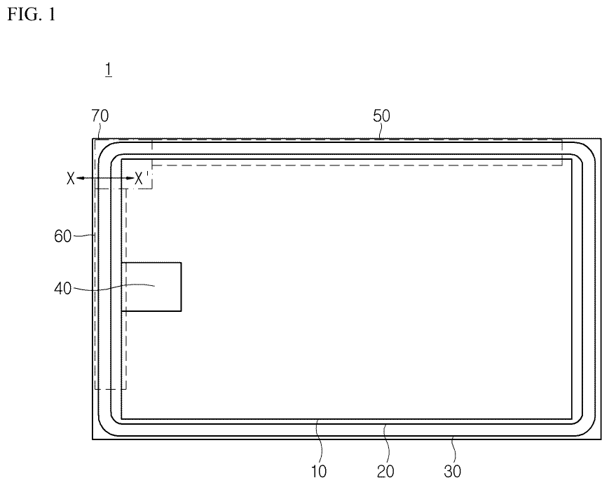

FIG. 1 is a plan view of a super-junction semiconductor device according to one embodiment of the present disclosure.

Referring to FIG. 1, the super-junction semiconductor device 1 may include an active cell 10, an edge termination region 30, and a peripheral region 20. In the super-junction semiconductor device 1, a cell region provided as the active cell 10 may be formed in a center area, the edge termination region 30 may surround the active cell 10, and the peripheral region 20 may be disposed between the active cell 10 and the edge termination region 30.

A gate pad 40 may be formed on one side within the center area of the active cell 10.

The edge termination region 30 and the peripheral region 20 may be distinguished by their respective locations. With respect to the active cell 10, edge/peripheral top and bottom regions 50 disposed on upper and lower areas of the active cell 10, edge/peripheral side regions 60 disposed on both sides of the active cell 10, and edge/peripheral corner regions connecting the edge/peripheral top and bottom regions 50 and the edge/peripheral side region 60.

Within the edge termination region 30 and the peripheral region 20, a charge-sharing region may be formed. The charge-sharing region may be formed in a ring shape within the edge termination region 30, and formed in a predetermined area within the peripheral region 20.

As will be described later, a plurality of second conductivity-type pillar layers may be formed within the peripheral region 20 and the edge termination region 30. The top layer of the second conductivity-type pillar layer may be connected to the charge-sharing region. The charge-sharing region may be formed near a surface of an epitaxial layer and have a limit to increasing the area. However, when the additional area is ensured by connecting the top layer of the second conductivity-type pillar layer and the charge-sharing region to each other, a hole current generated when a reverse bias is applied may be quickly dissipated and the reverse current slope value di/dt may be ensured.

When a reverse bias is applied, current may be locally concentrated in the edge termination area 30 and the peripheral region 20 located near the edge/peripheral corner region 70. In such cases, it may be desirable to ensure the di/dt value, which is the slope of the current movement path and reverse recovery current, to protect the device. That is, it may be desirable to increase the area of the charge-sharing area and the area of the top layer of the second conductivity-type pillar within the peripheral region and to increase the area of the source contact region within the peripheral region.

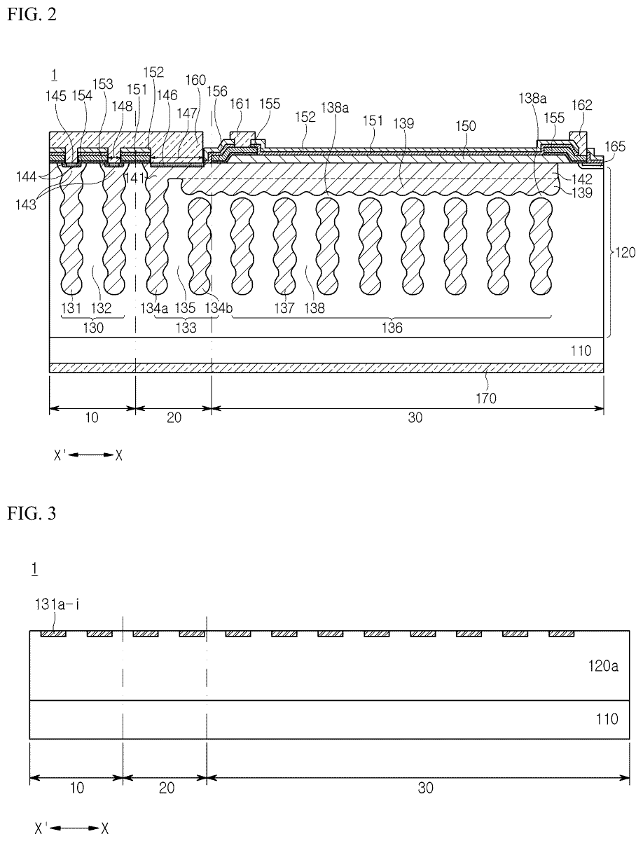

FIG. 2 shows the cross-section of the edge/peripheral corner region 70 to increase and ensure the area of the charge-sharing region and the area of the top layer of the second conductivity-type pillar.

FIG. 2 is a cross-sectional view showing the super-junction semiconductor device shown in FIG. 1 along X-X′.

Referring to FIG. 2, the super-junction semiconductor device 1 may include the active cell 10, the peripheral region 20, and the edge termination region 30. An epitaxial layer 120 may be formed on the substrate 110 of the super-junction semiconductor device 1 and a drain electrode 170 may be formed under the substrate 110.

The epitaxial layer 120 may be a region where a first conductivity-type impurity is doped. Within the epitaxial layer 120, a plurality of pillar regions may be formed. The plurality of pillar regions may include a first pillar region 130 having a vertical shape formed within the active cell 10; a second pillar region 133 having a vertical shape formed within the peripheral region 20; and a third pillar region 136 having a vertical shape formed within the edge termination region 30.

The first pillar region 130 may include a plurality of a vertical-shaped first conductivity-type (e.g., N-type) first pillar 132 N-pillar, and a second conductivity-type (e.g., P-type) first pillar 132 P-pillar. The second conductivity-type first pillar 131 may be formed between a first conductivity-type first pillar 132 and another first conductivity-type first pillar 132. A second conductivity-type body area 143 may be formed on a top layer of a second conductivity-type first pillar 131. The second conductivity-type first pillar 131 and the second conductivity-type body region 143 may be connected to each other. A first conductivity-type source region 144 may be formed in the body region 143. A second conductivity-type body contact region 145 may be formed between the source regions 144. The body contact region 145 may be formed on a surface of an epitaxial layer 120.

The gate insulating film 154 may be formed on a predetermined area of the body region 143, the first conductivity-type first pillar 132, and the source region 144 disposed within the active cell 10. The gate insulating film 154 may be formed on the body region 143, the first conductivity-type first pillar 132, and the charge-sharing region 141 at the boundary between the active cell 10 and the peripheral region 20.

A field plate insulating film 156 may be formed within the edge termination region 30, and formed on the end and side surfaces of the field oxide film 150 in a direction of the peripheral region 20 and on the charge-sharing region 142 of the edge termination region 30 adjacent to the peripheral region 20. In addition, the field plate insulating film 156 may be formed on the end and side surfaces of the field oxide film 150 in a direction of the edge/peripheral regions 50 and 60 and on the epitaxial layer 120.

A gate electrode 153 may be formed on the gate insulating film 154. The first insulating film 151 may be formed on the side and top surfaces of the gate electrode 153, and the second insulating film 152 may be formed on the first insulating film 151.

A source electrode 160 may be formed on the body contact region 145, and may be in ohmic contact with the body contact region 145.

The vertical-shaped second pillar region 133 provided within the peripheral region 20 may include a plurality of a first conductivity-type second pillar 135 and second conductivity-type second pillars 134a and 134b. The second conductivity-type second pillars 134a and b may be formed between a first conductivity-type second pillar 135 and another first conductivity-type second pillar, and the second conductivity-type pillars 134a and 134b may be distinguished by the regions. A 2-1 pillar 134a disposed adjacent to the active cell and a 2-2 pillar 134b disposed adjacent to the edge termination region.

Each of the 2-1 pillar 134a and 2-2 pillar 134b may be provided in plural in another embodiment.

A vertical-shaped third pillar region 136 disposed within the edge termination region 30 may include a first conductivity-type third pillar 138 and a second conductivity-type third pillar 137. The second conductivity-type third pillar 137 may be formed between a first conductivity-type third pillar 138 and another first conductivity-type third pillar 138.

A horizontal second conductivity-type fourth pillar 139 may be formed on the second conductivity-type 2-2 pillar 134b disposed within the peripheral region 20 and plural ones of second conductivity-type third pillar 137 disposed within the edge termination region 30.

The second conductivity-type second pillars 134a, b and the second conductivity-type third pillar 137, which are disposed within the peripheral region 20 and the edge termination region 30, may be formed together during the process of forming the epitaxial layer 120 by laminating the plurality of epitaxial layers. Hence, a mask may be patterned to form the positions where the second conductivity second pillars 134a and b and the second conductivity-type third pillar 137 can be formed, so that second conductivity-type ions are injected. By making the width of the opening the same, a vertical-shaped second conductivity-type pillar layer may be formed as meeting the second conductivity-type ions injected into the previous epitaxial layer by diffusion. In contrast, in a process of forming the second conductivity-type 2-2 pillar 134b formed in the peripheral region and the top layer of the second conductivity-type third pillar 137, the width of the mask opening for injecting ions on the second conductivity-type 2-2 pillar 134b within the peripheral region 20 and plural ones of the second conductivity-type third pillar 137 within the edge termination region 30 may be made narrower than the width of the mask opening for forming the vertical-shaped pillar, to form a vertical-shaped second conductivity-type fourth pillar region 139.

Specifically, for example, the width of the ion injection mask opening up to the epitaxial layers of the first to fourth layers may be made the same, and then vertical-shaped second conductivity pillars 134a and b and the second conductivity-type third pillar 137. The width of the ion-injecting mask opening on the epitaxial layer of the fifth layer may be reduced by half of the width of the ion-injecting mask opening on the epitaxial layers of the first to fourth layers. Hence, the range of ion injection diffusion may be expanded in the left and right direction, and a horizontal second conductivity-type fourth pillar region 139 may be formed. The width of the ion-injecting mask opening mentioned above is one of the examples, and the present disclosure is not limited thereto.

The horizontal second conductivity-type fourth pillar region 139 may be spaced apart from the second conductivity-type 2-2 pillar 134b and the top of the second conductivity-type third pillar 137. The first conductivity-type fourth pillar 138a may be formed in a space defined by the horizontal second conductivity-type fourth pillar region 139, the second conductivity-type 2-2 pillar 134b and the second conductivity-type third pillar 137.

The charge-sharing region 141 and 142 may be formed on the peripheral region 20 and the surface of the epitaxial layer 120 of the edge termination region 30. The charge-sharing region may be a second conductivity-type. The charge-sharing region 142 within the edge termination region 30 and the charge-sharing region 141 within the peripheral region 20 may be formed by an ion injecting process and an annealing process, respectively. The charge-sharing region 141 within the peripheral region 20 may be indicated as the peripheral charge-sharing region 141, and the charge-sharing region 142 within the edge termination region 30 may be indicated as the edge termination charge-sharing region 142. The peripheral charge-sharing region 141 and the edge termination charge-sharing region 142 may be connected to each other. The second conductivity-type 2-1 pillar 134a of the peripheral region 20 may be connected to the peripheral charge-sharing region 141, the edge termination charge-sharing region 142 and the vertical-shaped second conductivity-type fourth pillar region 139 formed thereunder. The edge termination charge-sharing region 142 may be connected to the vertical-shaped second conductivity-type fourth pillar region 139 and the peripheral charge-sharing region 141.

After the edge termination charge-sharing region 142 is formed, the peripheral charge-sharing region 141 and the body region 143 may be formed. When the peripheral charge-sharing region 141 is formed, it may be connected to the edge termination charge-sharing region 142 by a heat diffusion process to form one charge-sharing region.

The body contact region 145 may be formed in the body region 143 of the active cell 10, and the peripheral charge-sharing contact region 146 may be formed within the peripheral charge-sharing region 141 at the same time.

The peripheral contact region 147 may be formed by contacting the peripheral charge-sharing contact region 146. As another example, the peripheral contact region 147 may be formed by simultaneously contacting the peripheral charge-sharing region 141 and the peripheral charge-sharing contact region 146 based on the design of the width of the contact region.

In order to improve the reverse recovery current characteristics, it may be desirable to optimize the rear or length of the charge-sharing region formed within the peripheral region 20 as well as to optimize the length and area of the peripheral contact region. For example, when the cross-section of the peripheral contact area 147 increases, the hole current contact resistance generated during reverse bias may be effectively dissipated by reducing the contact resistance and then the di/dt value, which is the slope value of a stable reverse recovery current, may be ensured.

The source electrode 160 may be formed on the peripheral contact region 147 of the peripheral region 20 and the body contact region 145 and the source contact region 148 of the active cell 10.

The field oxide film 150 may be formed on the edge termination charge-sharing region 142 within the edge termination region 30.

The field plate 155 may be formed on a lateral wall of the field oxide film 150. The field plate 155 may be located at one end of the field oxide film 150 toward the peripheral region 20, and may be formed on the field oxide film 150 and the field plate insulating film 156. The field plate 155 may act as a field alleviator.

A gate runner 161 may be formed on the field plate 155. The gate runner 161 may be formed simultaneously with the formation of the source electrode 160. The gate runner 161 may be connected to a gate pad along the line of the outer termination region 30.

A guard ring or floating electrode 162 may be formed at an end of the peripheral/edge 50 and 60 regions of the edge termination region 30. An edge junction region 165 may be formed under the floating electrode 162. The edge junction region 165 may function as a channel stopper configured to stop the electric field generated when reverse bias is applied.

The concentration of the edge termination charge-sharing region 142 formed within the edge termination region 30 may be lower than the concentration of the peripheral charge-sharing region 141, and the edge termination charge-sharing region 142 and the peripheral charge-sharing region 141 may be connected to each other and arranged on the surface of the epitaxial layer 120. The charge-sharing regions 141 and 142 formed within the edge termination region 30 and the peripheral region 20 may be referred to as a P-type pillar buried region (i.e., PBR: P-buried region or P-type top layer region (i.e., P-top layer region).

The charge-sharing regions 141 and 142 disposed within the edge termination region 30 and the peripheral region 20 may be connected to each other and formed in contact with the surface of the epitaxial layer 120. Through this, it is possible to prevent stress caused by an electric field induced by a high breakdown voltage in the device off-state and a phenomenon in which a high lattice temperature is locally concentrated on the surface of the epitaxial layer 120, and to prevent the field oxide film 150 formed on the upper epitaxial layer 120 of the edge termination region 30 from being damaged by a high electric field.

FIGS. 3 to 19 are cross-sectional views showing a series of processes of a manufacturing method of the super-junction semiconductor device according to one embodiment of the present disclosure.

Referring to FIG. 3, the active cell 10, the peripheral region 20 and the edge termination region 30 may be formed on the substrate 110.

A multi epitaxial process for forming a plurality of epitaxies may be performed on the substrate 110.

First, a first epitaxial layer 120a may be formed on the substrate 110. The thickness of the first epitaxial layer 120a may be 15 to 30 um (i.e., 10⁻⁶ m).

The substrate 110 may be a semiconductor substrate 110 doped with a first conductivity-type, and the first epitaxial layer 120a may be also an epitaxial layer 120a doped with a first conductivity-type. The epitaxial layer 120a doped with the first conductivity-type may be formed by using materials such as phosphine (PH3) and arsine (AsH3) together during the epitaxial process.

The first conductivity-type may be additionally doped on the first epitaxial layer 120a, which may be referred to as a first conductivity blanket ion injection process. The concentration of the first conductivity-type ions on the surface of the first epitaxial layer 120a may be increased by injecting ions onto the first epitaxial layer 120a in the first conductivity-type blanket ion injection process.

After that, a first mask (not shown) may be disposed on the first epitaxial layer 120a. The first mask may be patterned to expose a portion 131a-I of the first epitaxial layer 120a, into which a second conductivity-type (e.g., P-type) impurity is injected. A second conductivity-type ion may be injected into the exposed portion 131a-I of the epitaxial layer 120, and a first implant layer may be then formed. After the first implant layer is formed, the first mask may be eliminated.

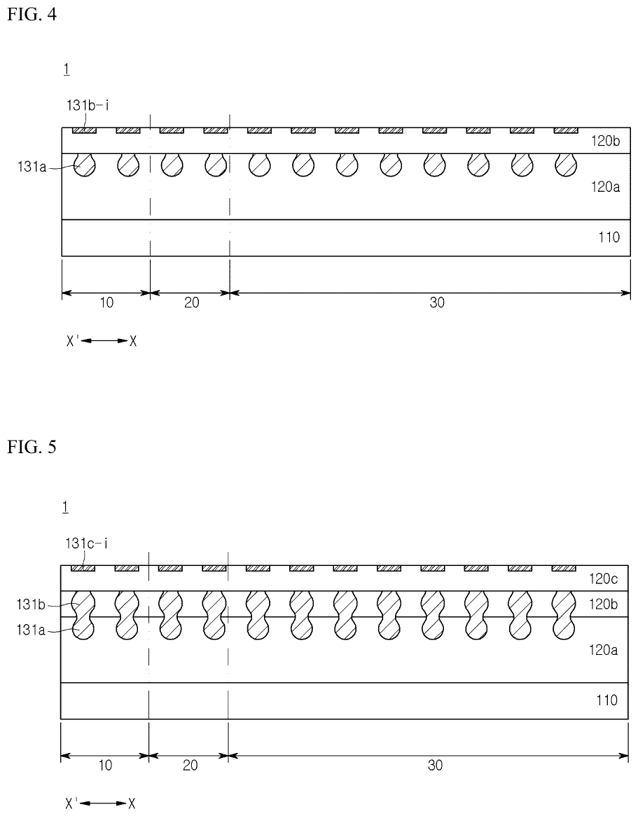

Referring to FIG. 4, a second epitaxial layer 120b may be formed on the first epitaxial layer 120a. An epitaxial process for forming the second epitaxial layer 120b may include a high-temperature annealing process. Due to the annealing process used in the epitaxial process for forming the second epitaxial layer 120b, the first implant layer 131a-i may be diffused to form the second conductivity-type first pillar layer 131a. While the first implant layer 131a-i is being diffused, the diffusion of second conductivity-type pillar ions 131a in the left-right direction may decrease and the diffusion of them in the up-down direction due to the first conductivity blanket ions formed between the second conductivity-type first implant layer, thereby forming the vertical-shaped pillar structure. Accordingly, the breakdown voltage characteristics can be improved by balancing the P/N charge.

When forming the second epitaxial layer 120b, the process temperature may be approximately 900° to 1300°. The thickness of the second epitaxial layer 120b may be formed to be the same as or smaller than the thickness of the first epitaxial layer 120a. After the second epitaxial layer 120b is formed, the first conductivity-type blanket ion injection process may be additionally formed.

Hence, a second mask may be disposed on the second epitaxial layer 120b. After that, a second mask (not shown) may be disposed on the second epitaxial layer 120b. The second mask may be patterned to expose a portion 131b-i of the second epitaxial layer 120b, into which a second conductivity-type ion is injected. A second conductivity-type ion may be injected into the exposed mask pattern of the second epitaxial layer 120b, and a first implant layer may be then formed. After the second implant layer 131b-i is formed, the second mask may be eliminated.

Referring to FIG. 5, a third epitaxial layer 120c may be formed on the second epitaxial layer 120b. An epitaxial process for forming the third epitaxial layer 120c may include a high-temperature annealing process. In the epitaxial process for forming the third epitaxial layer 120c, the second implant layer 131b-i may be diffused to form the second conductivity-type second pillar layer 131b. The second conductivity-type first pillar layer 131a and the second pillar layer 131b may be connected to each other.

The thickness of the third epitaxial layer 120c may be formed to be the same as or smaller than the thickness of the second epitaxial layer 120b. After the third epitaxial layer 120c is formed, the first conductivity-type blanket ion injection process may be additionally formed.

Hence, a third mask (not shown) may be disposed on the third epitaxial layer 120c. The third mask may be patterned to form a mask pattern with a predetermined width W1. A portion into which a second conductivity-type ion is injected may be exposed on the third epitaxial layer 120c. A second conductivity-type ion injection process may be performed and a third implant layer 131c-i may be formed. After the third implant layer 131c-i is formed, the third mask may be eliminated.

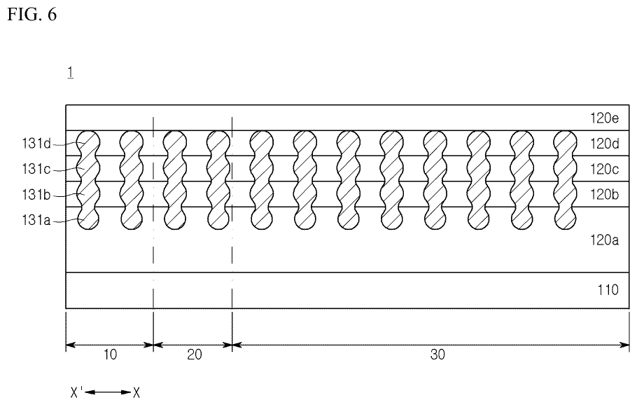

Referring to FIG. 6, a fourth epitaxial layer 120d and a fifth epitaxial layer 120e may be formed by repeating the process described in FIG. 4 or 5, and a fourth pillar layer 131c and a fourth pillar layer 131d may be formed. The second conductivity-type first to fourth pillar layers 131a to 131d may be diffused to be connected as one vertical-shaped pillar.

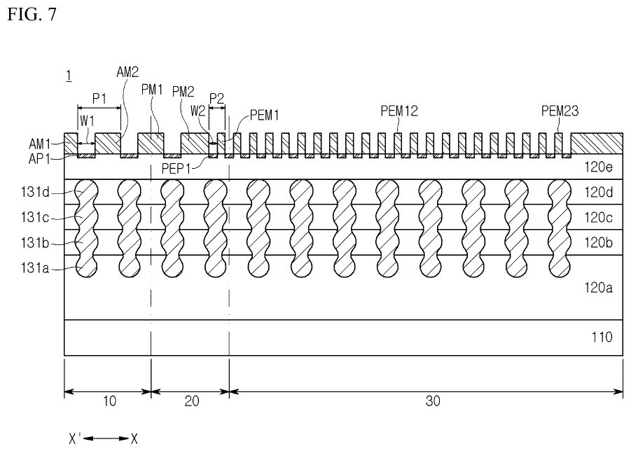

Referring to FIG. 7, in the process of forming the fifth implant layer, the width W2 of the mask opening for ion injection may be varied in the process of forming the implant layer within the peripheral region 20 and the edge termination region 30.

A fifth mask may be disposed on the fifth epitaxial layer 120e. To inject a second conductivity-type ion for forming a fifth implant layer, a plurality of openings may be patterned on the fifth mask.

The fifth mask of the peripheral region 20 adjacent to the active cell 10 may be divided into an active cell patterning mask AM1 and AM2 and a peripheral region patterning mask PM1 by region. The opening width W1 of the active cell patterning mask AM1 and AM2 and the peripheral region patterning mask PM1 may be formed to be the same as the mask opening width in the process of forming the first to fourth implant layers. In contrast, the width of the opening between the peripheral region patterning mask PM2 and the peripheral edge region patterning mask PEM1 of the fifth mask of the edge termination region 30 and the edge termination region 30 and the width W2 of the opening between the peripheral edge termination region patterning mask PEM1 to PEM 23 may be smaller than the opening width W1 of the active region patterning mask AM1 and AM2. According to one embodiment, W2 may be formed as narrow as 0.5 times that of Sq, but embodiments are not limited thereto.

The pitch P2 representing the sum of the width of the peripheral edge termination region patterning mask PEM1 and the width W2 of the opening may be formed narrower than the pitch P1 representing the sum of the width of the patterned mask AM2 of the active cell 10 and the width of the opening W1. In addition, the width of the fifth peripheral edge implant layer PEP 1 formed by injecting the second conductivity-type ion into the fifth epitaxial layer 120e of the peripheral region 20 and the edge termination region adjacent to the peripheral region 20 may be narrower than the width of the fifth active implant layer AP 1 formed by injecting the second conductivity-type ion into the fifth epitaxial layer 120e of the active cell 10 and the peripheral region 20 adjacent to the active cell 10.

During the process of forming the fifth peripheral edge implant layer of the edge termination region 30 and the peripheral region adjacent to the edge termination region, the ions of the fifth peripheral edge implant layer may be diffused in the left-right direction in the annealing process by narrowing the width (i.e., pitch) of the fifth peripheral edge implant layer, to be connected to another adjacent fifth peripheral edge implant layer. The ions of the fifth implant layer diffused in the state of having the narrow left-right-direction width may contact the ions injected nearby, thereby forming the vertical-shaped pillar structure. This may be referred to as the fifth vertical pillar layer or vertical-shaped second conductivity fourth pillar region 139.

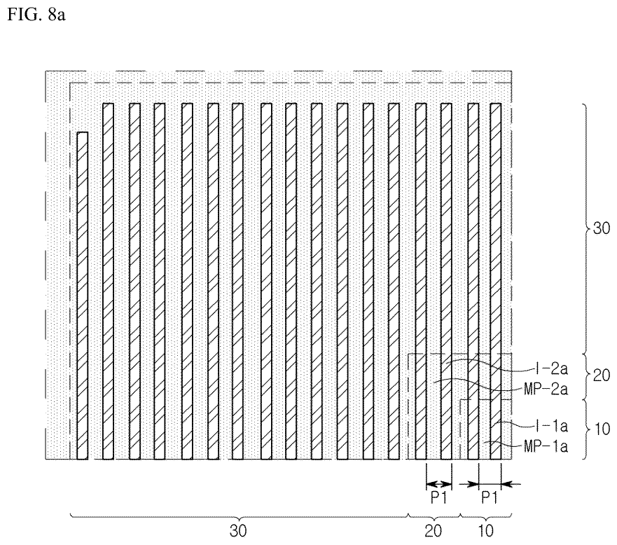

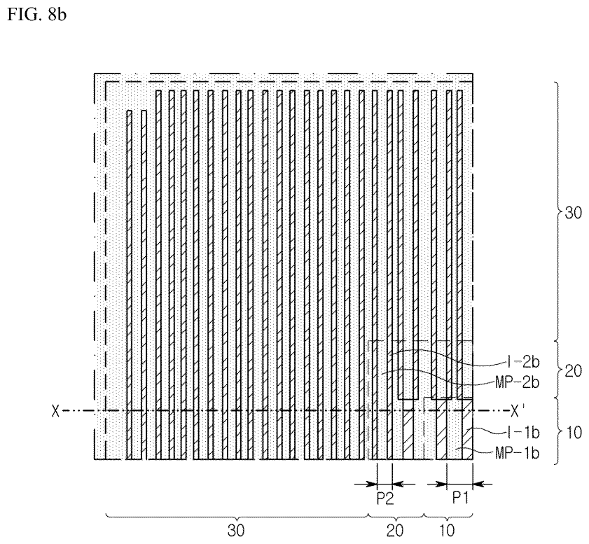

FIG. 8a is a plane view of the fourth implant layer seen from the top after the process of injecting ions into the fourth implant layer, and FIG. 8b is a plane view of the fifth implant layer seen from the top after the process of injecting ions into the fifth implant layer.

Referring to FIG. 8a, FIG. 8a shows one embodiment of the present disclosure. As shown in FIG. 6, the first to fourth implant layers may be formed at the same intervals in the active cell 10, the peripheral region 20 and the edge termination region 30. According to device characteristics, more epitaxial layers and implant layers may be formed. The widths of the mask pattern MP-1a and MP-2a and the fourth implant layer I-1a and I-2a may be the same in the active cell 10, the peripheral region 20 and the edge termination region 30. The pitch P1 indicating the distance between the starting point of one implant layer and the starting point of another adjacent implant layer in the active cell 10 may be the same as the pitch P1 indicating the distance between the starting point of one implant layer and the starting point of another adjacent implant layer in the peripheral region 20 and the edge termination region 30. During the process of forming the fourth pillar layer, even though the implant layers are diffused in the peripheral region and the edge termination region by the annealing process, the implant layers may have the predetermined left-right distance or more therebetween, thereby being formed to have the vertical-shaped pillar structure that is independently configured without being attached to each other.

Referring to FIG. 8b, FIG. 8b shows one embodiment of the present disclosure. As shown in FIG. 7, the first to fourth implant layers may be formed in the active cell 10, the peripheral region 20 and the edge termination region 30 at the same pitch, thereby forming the vertical-shaped pillar structure. In contrast, the fifth pillar layer, that is the top layer, may be formed different from the active cell by controlling the pitch of the mask pattern for the ion injection process for forming the fifth implant layer in the peripheral region 20 and the edge termination region 30. In the active cell 10, the width of the mask pattern MP-1b and the width of the fifth implant layer 1-1b may be formed in the same manner as in the process of forming the first to fourth implant layers, but the width of the mask pattern MP-2b and the width of the fifth implant layer 1-2b in the peripheral region 20 and the edge termination region 30 may be formed narrower than the width in the active cell 10. Accordingly, the pitch P2, which indicates the distance between the starting point of one implant layer and the starting point of another implant layer in the peripheral region 20 and the edge termination region 30, may be formed narrower than the pitch P1 in the active cell 10. For example, the distance of P2 may be ½ times the distance of P1, but the embodiments are not limited thereto.

As described in FIGS. 8a and 8b, the first to fourth implant layers have the independent vertical-shaped pillar structure after the annealing process, while the fifth implant layer has a half pitch structure with the pitch spacing reduced by half compared to the full pitch structure of the first and fourth implant layers. After the annealing process, the fifth implant layer may be connected to each other in the peripheral region 20 and the edge termination region 30 to form the single horizontal-shaped pillar layer. After that, the charge charging region formed in the process may be connected to ensure the area of the wide charge-sharing region, thereby securing the stable breakdown voltage and slope values of reverse recovery current may be ensured.

After the edge termination charge-sharing region 142 is formed, the peripheral charge-sharing region 141 and the body region 143 may be formed. When the peripheral charge-sharing region 141 is formed, it may be connected to the edge termination charge-sharing region 142 to be formed as one charge-sharing region.

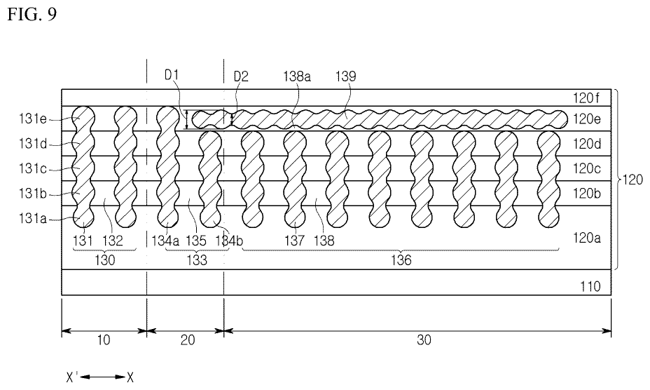

Referring to FIG. 9, a horizontal-shaped second conductivity-type fourth pillar region 139 may be formed within the peripheral region and the edge termination region.

A sixth epitaxial layer 120f may be formed on the active cell 10, the peripheral region 20 and the edge termination region 30. In the annealing process applied when forming the sixth epitaxial layer 120f, ions injected into the fifth implant layer AP 1 and PEP 1 may be diffused. Due to that, the fifth implant layer formed to have the same pitch as the first to fourth pillar layers within the active cell 10 may be diffused in the vertical direction to form the fifth pillar layer 131e and connected to the fourth pillar layer 131d. the fifth implant layer PEP 1 disposed within the peripheral region 20 and the edge termination region 30 may be diffused horizontally by the predesigned controlling of the pitch value and then may contact each other to form one horizontal-shaped pillar layer. One horizontal-shaped pillar layer, that is, the horizontal-shaped second conductivity fourth pillar region 139 may be spaced apart a preset distance from the vertical-shaped second conductivity second pillar 134b and the third pillar 137 formed by connecting the first to fourth pillar layers of the peripheral region and the edge termination region 30 to each other. As the horizontal-shaped second conductivity-type fourth pillar region 139, the vertical-shaped second conductivity 2-2 pillar 134b and the third pillar 137 are not connected, the first conductivity-type fourth pillar 138a may be formed among the horizontal-shaped second conductivity-type fourth pillar 139, the vertical-shaped second conductivity-type 2-2 pillar 134 and the third pillar 137.

In the horizontal-shaped second conductivity-type fourth pillar region 139, the first thickness D1 in the region where the second conductivity-type ion is injected may be greater than the second thickness D2 in the region where ions are diffused to be connected.

The width of the second conductivity-type 2-1 pillar 134a formed in the peripheral region 20 adjacent to the active cell 10 may be the same as the width of the second conductivity pillar formed within the active cell 10, which may be referred to as the dummy pillar region.

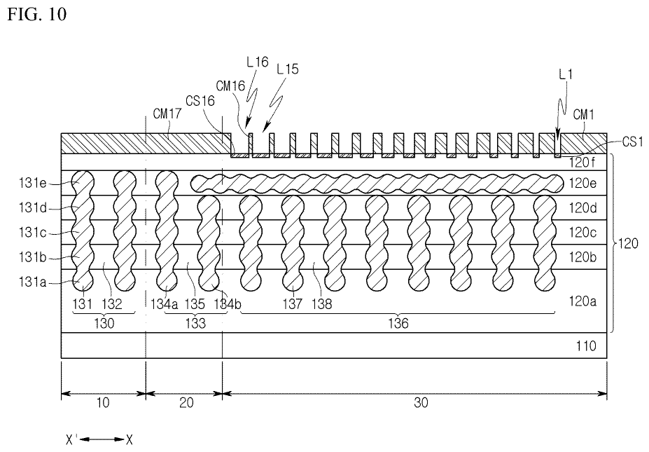

Referring to FIG. 10, the ion injection process may be performed to form the edge termination charge-sharing region 142 within the edge termination region 30.

Edge charging sharing masks CM1 to CM17 may be disposed on the sixth epitaxial layer 120f. To inject the second conductivity ion for forming the edge termination charge-sharing region 142 into the sixth epitaxial layer 120f, a plurality of openings L1 to L16 may be patterned on the edge termination charge-sharing mask CM1 to CM17.

The second conductivity ion may be injected on the openings L1 to L16 of the edge termination charge-sharing mask, to form the edge termination charge-sharing ion injection layers CS1 to CS16.

The concentration of the edge termination charge-sharing ion injection layer CS1 to CS16 may be the same or lower than the concentration of the fifth pillar layer 131e.

The widths of the edge termination charge-sharing ion injection layers CS1 to CS16 may be formed differently based on the widths of the openings L1 to L16 of the edge charge-sharing mask. The widths of the edge termination charge-sharing ion injection layers CS1 to CS16 may gradually increase as getting close to the peripheral region 20 from the edge termination region 30.

If the amount of second conductivity-type charge is high in the portion adjacent to the edge charge-sharing mask CM1 of the edge termination region, the electric field might be concentrated, which could reduce the reliability of the product. Accordingly, by making the width of the edge termination charge-sharing ion injection layer adjacent to the edge charge-sharing mask CM1 narrower than the width of other charge-sharing ion injecting layers, the amount of injected charge may be made relatively small and the electric field adjacent to the edge region may be expanded. It may be desirable to extend the electric field to the guarding region (i.e., floating electrode 162) by balancing the second conductivity-type charge amount and the first conductivity-type charge amount in the edge termination charge-sharing region 142, and when the balance is right, an appropriate breakdown voltage may be ensured.

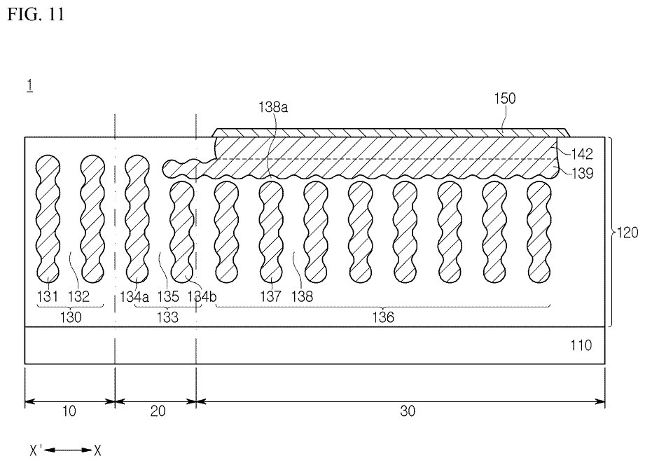

Referring to FIG. 11, the annealing process may be performed to diffuse the second conductivity-type ions of the edge termination charge-sharing ion injection layer, thereby forming the edge termination charge-sharing region 142. The edge termination charge-sharing region 142 may be formed by diffusing to the surface of the epitaxial layer 120 through thermal diffusion and contacting or bonding with the surface side. In addition, the edge termination charge-sharing region 142 may be diffused the horizontal-shaped second conductivity-type fourth pillar 139 formed within the edge termination region 30 and the peripheral region 20, to be formed in the horizontal structure in which they are connected to each other.

The temperature in the annealing process may be approximately 1000° C. to 1300° C. and the time may be 100 to 200 minutes. Such the high-temperature annealing process may sufficiently disuse even the pillar regions formed under the edge termination charge-sharing region 142, thereby forming a more stable vertical-shaped pillar structure and horizontal-shaped pillar structure. Accordingly, a high breakdown voltage can be ensured. In addition, the horizontal-shaped second conductivity-type fourth pillar 139 may be diffused more to be connected to the edge termination charge-sharing region 142, thereby securing the slope value of stable reverse recovery current.

Referring to FIG. 11, the field oxide film 150 may be formed on the surface of the epitaxial layer 120 after the edge termination charge-sharing region 142 is formed. A mask may be disposed on the field oxide film 150 on the edge termination charge-sharing region 142 and then the field oxide film may be etched from the area except the area where the mask is disposed, thereby forming the field oxide film 150 on the edge termination charge-sharing region 142. The field oxide film 150 may be formed through an oxidation process, and the oxide film may be made of materials such as silicon oxide, silicon oxynitride, and silicon nitride.

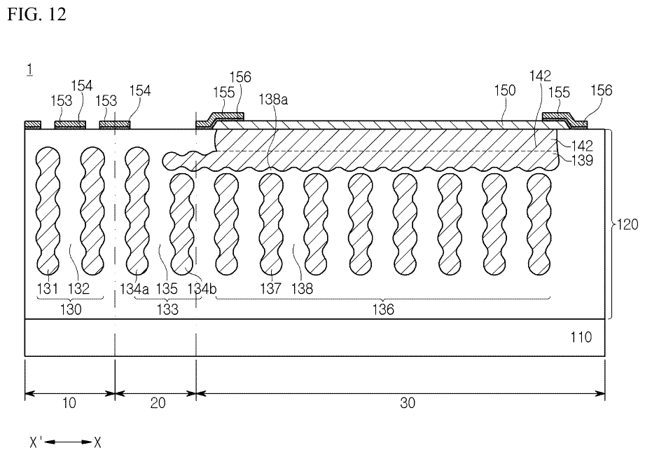

Referring to FIG. 12, the gate insulating film 154, the gate electrode 153, the field plate insulating film 156 and the field plate 155 may be formed.

At this time, the field plate insulating film 156 and the gate insulating film 154 may be deposited simultaneously. According to one embodiment, the insulating film may be deposited on the entire area of the active cell 10, the peripheral region 20 and the edge termination region 30. A polysilicon layer may be deposited on the insulating film, and the insulating film and the polysilicon layer may be etched together to form the gate insulating film 154, the gate electrode 153, the field plate insulating film 156 and the field plate 155. According to one embodiment, the resistance of the gate electrode 153 may be reduced by additionally injecting phosphorus ions during the deposition of the polysilicon layer.

The field plate 155 may be formed the field oxide film 150 and the field plate insulating film 156 of the edge termination region 30. The field plate 155 may be formed on the side and upper surface of the field plate insulating film 156 and the field oxide film 150 located at the boundary area of the edge termination region 30 and the peripheral region 20.

The gate electrode 153 may be formed on the gate insulating film 154 of the active cell 10. The gate electrode 153 may also be formed on the gate insulating film 154 located at the boundary area of the active cell 10 and the peripheral region 20.

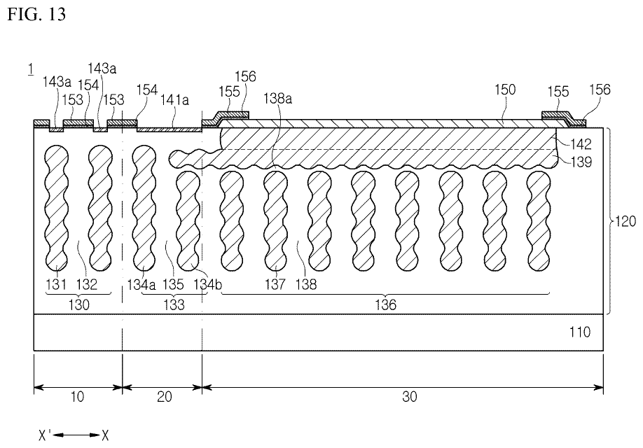

Referring to FIG. 13, the process of injecting the second conductivity-type ions into the active cell 10 and the peripheral region 20 may be performed. The second conductivity-type ion injection process may form the body region 143 within the active cell 10 and the peripheral charge-sharing region 141 within the peripheral region 20 by using the gate electrode 153 and the field plate 155 as masks. The second conductivity-type ion injection layer 143a and 141a may be formed within the active cell 10 and the peripheral region 20 by performing the second conductivity-type ion injection process. By using the gate electrode 153 and the field plate 155 as masks, the process steps may become simplified and process costs may be reduced. This second conductivity-type ion injection process may also be called the P-well ion injection process.

The concentration of the second conductivity-type impurity 141a and 143a injected in the second conductivity-type ion injection process may be higher than the concentration of the second conductivity-type impurity injected in the edge termination charge-sharing region 142.

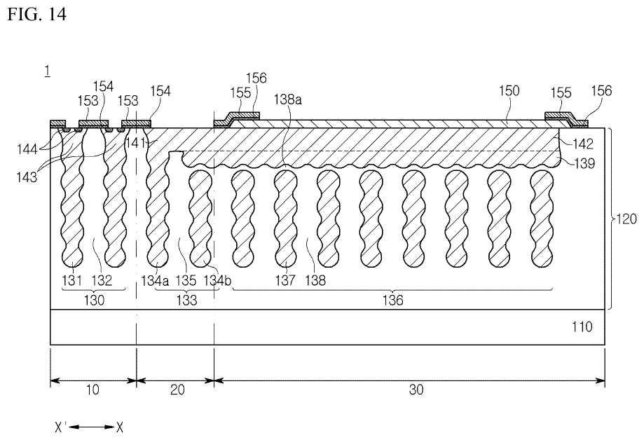

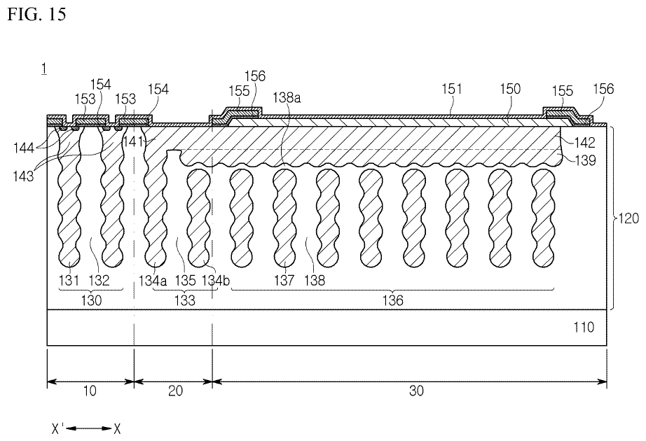

Referring to FIG. 14, the second conductivity-type ion injection layers 141a and 143a within the active cell 10 and the peripheral region 20 may be diffused through the annealing process, to form the second conductivity-type body region 143 and the second conductivity-type peripheral charge-sharing region 141.

The second conductivity-type body area 143 within the active cell 10 may be diffused to be connected to the first conductivity-type first pillar 131 disposed thereunder.

The second conductivity-type peripheral charge-sharing region 141 within the peripheral region 20 may be diffused to be connected to the second conductivity-type 2-1 pillar 134a disposed thereunder. In addition, the peripheral charge-sharing region 141 may be diffused to be connected to the edge termination charge-sharing region 142. The peripheral charge-sharing region 141 may be diffused to be connected to the horizontal-shaped second conductivity-type fourth pillar 139. The peripheral charge-sharing region 141 and the edge termination charge-sharing region 142 may be connected to the second conductivity-type 2-1 pillar 134a and the horizontal-shaped second conductivity-type fourth pillar 139 disposed thereunder.

In the annealing process applied to the second conductivity-type ion injection layers 141a and 143a within the active cell 10 and the peripheral region 20, the process temperature may be approximately 900° C. to 1300° C.

The charge-sharing region 141 and 142 may be referred to as the P-type buried region PBR or P-top layer region.

After that, a mask may be disposed between the gate electrodes 153 formed within the active cell 10 and the patterning process may be then performed, to expose only the portion for forming the source region 144. Then, the source ion injection process may be performed to form the source region 144. Th source region 144 may be extended even to some area under the gate electrode 153.

Referring to FIG. 15, the first insulating film 151 may be formed on the entire area including the gate electrode 153, the field plate 155 and the field oxide film 150. The first insulating film may be formed by using materials such as a silicon oxide film SiO₂, a silicon nitride film SiN, a silicon oxynitride film SiON, and a nitride film Nitrde. The deposition thickness of the first insulating film 151 can be deposited to a thickness of about 800 to 2000 Å (1 Å=10−10 m).

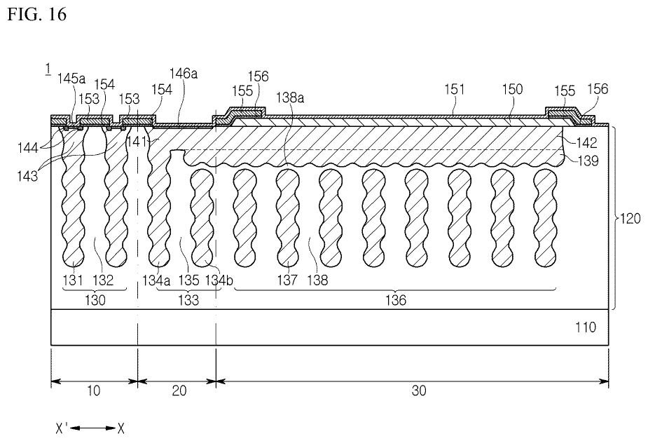

Referring to FIG. 16, a high-concentration second conductivity-type blanket ion injection process may be performed on the first insulating film 151 without a separate mask disposition. Accordingly, the body contact ion injection layer 145a within the active cell 10 and the peripheral charge-sharing contact ion injection layer 146a within the peripheral region 20 may be formed.

The first insulating film 151 with quite a thickness may be formed on the source region 144 within the active cell 10, so that the injection amount of ions reaching the source region 144 during the second conductivity-type blanket ion injection process may be minimized. In conventional art, a separate mask for blocking the source region 144 is additionally disposed but the embodiments of the present disclosure may perform the high-concentration second conductivity-type blanket ion injection process without a separate mask for protecting the source region 144 to form the body contact ion injection layer 145a, thereby simplifying the process steps and reducing the process costs.

The concentration of the body contact ion injection layer 145a may be higher than the concentration of the peripheral charge-sharing region 141.

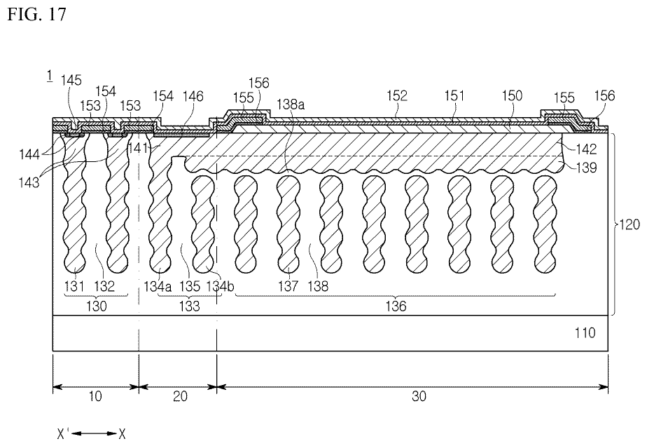

Referring to FIG. 17, the second insulating film 152 may be deposited on the first insulating film 151. After the second insulating film 152 is deposited, a thermal process may be performed for planarization of the second insulating film 152. At this time, due to the applied thermal process, the ions of the body contact ion injection layer may be diffusing and the second conductivity-type body contact region 145 may be formed during the diffusion. While the ions of the peripheral charge-sharing contact ion injection layer 146a are diffusing, the peripheral charge-sharing contact region 146 may be formed and the second insulating film 152 may be formed of BPSG (boron-phosphors silicate glass), PSG (phosphors silicate glass), etc. The thickness of the second insulating film 152 may be approximately 8000 to 12000 Å.

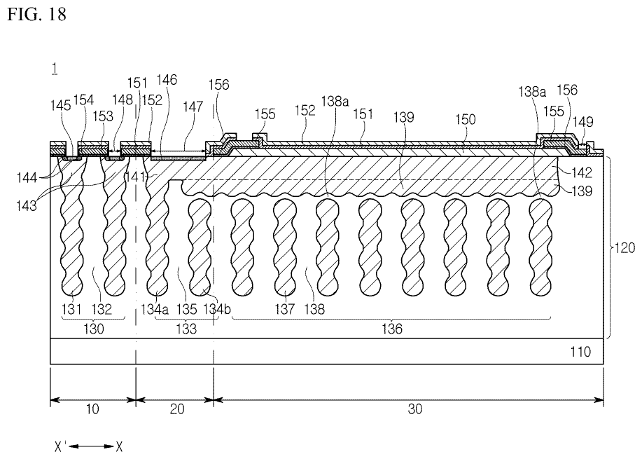

Since the second conductivity-type body contact region 145 and the peripheral charge-sharing contact region 146 are formed, the ohmic contact may be improved by supplementing the reduction of the contact layer during the subsequent contact etching process. Referring to FIG. 18, the source contact region 148, the peripheral contact region 147 and the gate runner contact region 149 may be formed by performing contact-etching on the first insulating film 151 and the second insulating film 152. As one embodiment, after a contact mask may be disposed on the first insulating film 151 and the second insulating film 152, the contact mask may be patterned and the first insulating film 151 and the second insulating film 152 may be etched, to expose contact regions. The body contact region 145 may be formed in the active cell 10 and the peripheral charge-sharing contact region 146 may be formed in the peripheral region 20. The gate runner contact region 149 may be simultaneously formed on the field plate 155 of the edge termination region 30. As the area of the peripheral charge-sharing contact region 146 increases, the contact area can increase, which results in reducing contact resistance more.

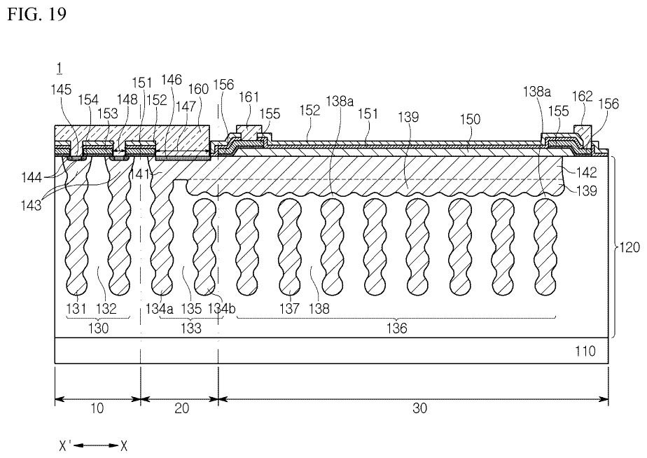

Referring to FIG. 19, a metal layer may be deposited on the contact-etched regions. As one example, the metal layer may be deposited on the active region, the peripheral region and the edge termination region. After that, a planarization process may be performed to planarize the deposited metal layer. The metal layer may be planarized through a CMP process. A mask may be disposed on the planarized metal layer and the mask may be patterned, which is the metal etching process. Through the metal etching process, the source electrode 160 to be connected to the source contact region 148 and the peripheral contact region 147 may be formed. In addition, the floating electrode 162 may be formed on the gate runner 161 to be connected to the field plate 155 and one end of the edge termination region 30.

During the process of depositing the metal layer, titanium Ti or titanium nitride to be functioned as a metal barrier, may be deposited, and tungsten W maya be then deposited in a contact hole and an etch-back process may be performed. Hence, an aluminum Al layer may be deposited on this deposited layer to form the metal layer. The CMP process may be performed to planarize the metal layer.

Next, a back grinding process may be performed on the substrate 110 to reduce the thickness of the substrate 110. The grinding process for the substrate 110 may reduce the thickness of the substrate 110 so as to reduce resistance within the substrate 110.

Hence, a lower metal layer may be formed. The lower metal layer may serve as the drain electrode 170. The lower metal layer may be deposited using materials such as nickel/vanadium and silver.

By performing the above-described process, the super-junction semiconductor element 1 can be formed that ensures an appropriate breakdown voltage and a slope value of a high reverse recovery current desired during reverse bias.

One or more embodiments may ensure an extended charge-sharing area by forming a single horizontal P-type pillar on the uppermost layer of multiple P-type pillars arranged within a peripheral region and an edge termination region and forming a charge-sharing region on the horizontal P-type pillar.

According to one or more embodiments, the extended charge-sharing area may be ensured by forming the single horizontal-shaped P-type pillar on the uppermost layer of multiple P-type pillars arranged within the peripheral region and the edge termination region and forming the charge-sharing region on the horizontal-shaped P-type pillar. Through this, it is possible to ensure a di/dt value, which is the slope value of the reverse recovery current when reverse bias is applied, and provide a super-junction semiconductor device capable of securing a stable breakdown voltage to prevent device destruction and the like.

One or more embodiments may ensure the robustness and ruggedness of a body diode by reducing contact resistance by sufficiently securing the area of a contact region formed in a peripheral region.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A super-junction semiconductor device comprising:
a substrate;
an active cell disposed on the substrate;
an edge termination region configured to surround the active cell;
a peripheral region configured to surround the active cell and disposed between the active region and the edge termination region;
a first conductivity-type pillar and a second conductivity-type pillar alternately disposed in the active cell, the peripheral region, and the edge termination region;
a horizontal-shaped second conductivity-type pillar region disposed on the second conductivity-type pillar in the peripheral region and the edge termination region; and
a second conductivity-type charge-sharing region disposed on the horizontal-shaped second conductivity-type pillar region.

2. The super-junction semiconductor device of claim 1, wherein the first conductivity-type pillar comprises:
a first conductivity-type first pillar disposed in the active cell;
a first conductivity-type second pillar disposed in the peripheral region;
a first conductivity-type third pillar disposed in the edge termination region,
wherein the second conductivity pillar comprises:
a second conductivity-type first pillar disposed in the active cell;
a second conductivity-type second pillar disposed in the peripheral region; and
a second conductivity-type third pillar disposed in the edge termination region, and
wherein a vertical direction of the second conductivity-type first pillar is longer than a vertical direction of the second conductivity-type third pillar.

3. The super-junction semiconductor device of claim 1, wherein the horizontal-shaped second conductivity-type pillar region is connected to the second conductivity-type charge-sharing region.

4. The super-junction device of claim 2, further comprising:
a first conductivity-type fourth pillar disposed between the second conductivity-type third pillar in the peripheral region and the horizontal-shaped second conductivity-type pillar.

5. The super-junction semiconductor device of claim 1, wherein the second conductivity-type charge-sharing region comprises:
a peripheral charge-sharing region disposed in the peripheral region; and
an edge termination charge-sharing region disposed in the edge termination region, and
wherein a charge concentration of the edge termination charge-sharing region is lower than a charge concentration of the peripheral charge-sharing region.

6. The super-junction semiconductor device of claim 2, further comprising:
a second conductivity-type body region disposed on the second conductivity-type first pillar;
a first conductivity-type source region disposed in the second conductivity-type body region; and
a second conductivity-type body contact region disposed between the first conductivity-type source region and another first conductivity-type source region in the second conductivity-type body region.

7. The super-junction semiconductor device of claim 6, further comprising:
a field oxide film disposed on the edge termination charge-sharing region in the edge termination region;
a field plate insulating film disposed above an end and sides of the field oxide film toward the peripheral region and on the edge termination charge-sharing region adjacent to the peripheral region; and
a gate insulating film disposed in the second conductivity-type body region, the first conductivity-type first pillar, and a predetermined area of the first conductivity-type source region.

8. The super-junction semiconductor device of claim 7, further comprising:
a gate electrode disposed on the gate insulating film;
a field plate disposed on the field insulating film; and
a gate runner disposed on the field plate.

9. The super-junction semiconductor device of claim 6, further comprising:
a peripheral contact region disposed on a peripheral charge-sharing region in the peripheral region;
a source electrode disposed on the second conductivity-type body contact region and the peripheral contact region; and
a drain electrode disposed under the substrate.

10. The super-junction semiconductor device of claim 2, wherein the second conductivity-type second pillar disposed in the peripheral region comprises:
a second conductivity-type 2-1 pillar disposed adjacent to the active cell, and
a second conductivity-type 2-2 pillar disposed adjacent to the edge termination region.

11. The super-junction semiconductor device of claim 10, wherein the second conductivity-type 2-1 pillar is connected to the second conductivity-type charge-sharing region and the horizontal-shaped second conductivity-type pillar region.

12. The super-junction semiconductor device of claim 10, wherein the second conductivity-type 2-2 pillar is spaced apart from the horizontal-shaped second conductivity-type pillar region.

13. A manufacturing method of a super-junction semiconductor device, comprising:
forming a semiconductor substrate;
forming plural ones of a vertical-shaped first conductivity-type pillar and a vertical-shaped second conductivity-type pillar in each of an active region, a peripheral region, and an edge termination region of the semiconductor substrate; and
forming a horizontal-shaped second conductivity-type pillar on the plural ones of the vertical-shaped first conductivity-type pillar and the vertical-shaped second conductivity-type pillar.

14. The manufacturing method of claim 13, wherein the forming of the plural ones of the vertical-shaped first conductivity-type pillar and the vertical-shaped second conductivity-type pillar comprises:
a first operation of forming a first epitaxial layer on the semiconductor substrate;
a second operation of injecting a second conductivity-type ion to the first epitaxial layer at a first interval;
a third operation of diffusing the second conductivity-type ion while forming a second epitaxial layer on the first epitaxial layer; and
an operation of forming up to a fifth epitaxial layer by repeating the first to third operations.

15. The manufacturing method of claim 14, further comprising:
a fourth operation of injecting a second conductivity-type ion into the active cell on the fifth epitaxial layer at the first interval, the peripheral region, and the edge termination region at a second interval narrower than the first interval.

16. The manufacturing method of claim 15, wherein the fourth operation comprises:
forming, on the fifth epitaxial layer, a mask comprising a first opening in the active cell at the first interval, and a second opening in the peripheral region and the edge termination region at the second interval; and
injecting a second conductivity-type ion to the fifth epitaxial layer through the mask, and
wherein a width of the second opening is narrower than a width of the first opening.

17. The manufacturing method of claim 16, wherein the width of the second opening is ½ of the width of the first opening, and
wherein the second interval is ½ of the first interval.

18. The manufacturing method of claim 16, further comprising:
diffusing the second conductivity-type ion injected into the fifth epitaxial layer to form the vertical-shaped second conductivity-type pillar in the active cell and the horizontal-shaped second conductivity-type pillar in the peripheral region and the edge termination region, while forming a sixth epitaxial layer on the fifth epitaxial layer.

19. The manufacturing method of claim 18, wherein a first thickness in an area where the second conductivity-type ion of the horizontal-shaped second conductivity-type pillar is injected is thicker than a second thickness of an adjacent area connected to the area by diffusing the second conductivity-type ion.

20. The manufacturing method of claim 13, further comprising:
forming an edge termination charge-sharing region to be connected to the horizontal-shaped second conductivity-type pillar above an epitaxial layer in the edge termination region;
forming a field oxide film on the epitaxial layer in the edge termination charge-sharing region and the edge termination region;
forming a gate insulating film on the vertical-shaped first conductivity-type pillar in the active cell of the semiconductor substrate, and forming a field plate insulating film at both ends of the field oxide film;
forming a gate electrode on the gate insulating film and a field plate on the field plate insulating film;
forming a body region on the vertical-shaped second conductivity-type pillar in the active cell, and forming a peripheral charge-sharing region on the epitaxial layer in the peripheral region to be connected to the vertical-shaped second conductivity-type pillar of the peripheral region, the horizontal-shaped second conductivity-type pillar, and the edge termination charge-sharing region;
forming a source region at an upper end of the body region;
forming a first insulating film on the gate electrode, the field plate, and the field oxide film;
forming a body contact region between the source region and another source region in the body region, and forming a peripheral contact region above the peripheral charge-sharing region;
forming a second insulating film on the first insulating film;
forming a source electrode connected to the body contact region and the peripheral contact region, and forming a gate runner connected to the field plate; and
forming a drain electrode under the semiconductor substrate.
